(19) United States
(12) Patent Application Publication
(10) Pub. No.: US 2007/0264585 A1
(43) Pub. Date: Nov. 15, 2007

(54) PHOTOMASK HAVING HALF-TONE PHASE SHIFT PORTION

(75) Inventor: Hiroshi YOSHINO, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/747,316

(22) Filed: May 11, 2007

(30) Foreign Application Priority Data
May 12, 2006 (JP) 2006-133354

(51) Int. Cl. G03F 1/00; G03F 9/00

(52) U.S. Cl. 430/5; 430/22

(57) ABSTRACT

A photomask has a half-tone phase shift portion in a reticle alignment mark portion instead of a light transmissive portion so as to reduce an exposure light transmittance and reduce an influence from ghost.

This application claims priority to prior Japanese patent application JP2006-133354, the disclosure of which is incorporated herein by reference.

### BACKGROUND OF THE INVENTION

1. Field of the Invention

The present invention relates to a photomask used for a lithography process to manufacture a semiconductor device, and more particularly to a photomask having a half-tone phase shift portion.

2. Description of the Related Art

As semiconductor devices have been highly integrated, device patterns have been enhanced in fineness. For example, dynamic random access memory products (DRAM) having a minimum dimension not more than 100 nm and a capacity of 1 gigabit have practically been used. Optical lithography technology serves as an engine of this enhancement of fineness. Optical lithography has made progress in reduction of the wavelength of exposure light. The wavelength of light source used in an exposure apparatus has been shortened as achieved by visible light rays (g-ray), ultraviolet rays (i-ray),+1) and excimer laser beams (KrF, ArF, and F₂). Super-resolution technology includes use of phase shift photomasks in addition to reduction of the wavelength of exposure light.

Phase shift photomasks can improve the resolution of patterns by shift modulation of a phase, which is one of properties of a wave motion of a light source. Phase shift photomasks include half-tone type photomasks and Levenson type photomasks. The half-tone type photomask has a quartz blank and a semitransparent film formed as a pattern on the quartz blank for phase shift. The semitransparent film has a transmittance of about 4% to about ten-odd percent. Cr-based metals or MoSi-based metals are used for the semitransparent film. The Levenson type photomask has a light shield film having a transmittance of 0%. A quartz blank is removed from portions having no light shield film patterns, and the phase of light is shifted by reducing the thickness of the photomask. Thus, the resolution of a pattern is improved by shifting the phase of light.

A method transferring a pattern in the related art will be described below with reference to FIGS. 1 to 3. In order to form a desired resist pattern on a semiconductor substrate, a photomask as shown in FIG. 2 has been used to perform an exposure process for pattern transfer. The photomask includes a product pattern portion 01 having a pattern to be transferred and a light shield area 21 disposed around the product pattern portion 01 for preventing patterns other than a product pattern from being transferred. Furthermore, alignment of the photomask is required for an overlay with a base pattern. The photomask includes reticle alignment mark portions 11 (see FIG. 3) used for this purpose. For example, the reticle alignment mark portion 11 is illustrated in FIG. 3 as having a light shield area 41 of a cross mark and a glass portion (transparent portion) 31 other than the light shield area 41.

As described above, with recent progress of fineness, the wavelength of exposure light has been shortened. As a consequence, light leakage (ghost) from a light shield zone has been increased. Furthermore, variations of the pattern dimension and pattern defects caused by ghost have become issues because of shortage of margins for light exposure. Accordingly, when a pattern was formed by the use of an existing photomask, the dimension of the resist pattern was partially reduced as shown in FIG. 1.

The dimension of the resist pattern was reduced at portions near the reticle alignment mark portions 11 provided in the light shield area 21, which was provided around the product pattern portion 01. Light leaked from the reticle alignment mark portions reacts with the resist. As a result, the resist near the reticle alignment mark portions becomes overexposed. Thus, the dimension of the resist pattern is reduced. In this manner, variations of the pattern dimension and pattern defects caused by ghost have become issues because of increase of light leakage (ghost) from a light shield zone and shortage of margins for light exposure.

The following patent documents relate to such a half-tone type phase shift photomask. Japanese laid-open patent publication No. 10-83062 (Patent Document 1) discloses a light shield layer provided at four corners of a semitransparent portion so as to prevent light leakage. Japanese laid-open patent publication No. 9-205055 (Patent Document 2) discloses an alignment apparatus using a half-tone phase shift photomask with high reflective plates provided below the mask so as to obtain a reflected image having a high contrast. However, these documents are silent on variations of the pattern dimension due to overexposure of a resist that is caused by light leaked from a reticle alignment mark.

### SUMMARY OF THE INVENTION

As described above, there is a problem that the dimension of a resist pattern is reduced at a portion near a reticle alignment mark portion. The present invention has been made in view of this problem. It is, therefore, an object of the present invention to provide a photomask having a half-tone phase shift portion which can reduce variations of pattern dimension and pattern defects caused by ghost.

In order to resolve the above problem, the present invention basically adopts the following technology. As a matter of course, the present invention covers applied technology in which various changes and modifications are made without departing from the spirit of the present invention.

According to an aspect of the present invention, there is provided a photomask for transferring a product pattern onto a semiconductor wafer. The photomask includes a reticle alignment mark portion having no light transmissive portion.

In the photomask of the present invention, the reticle alignment mark portion may have a half-tone phase shift portion instead of the light transmissive portion.

In the photomask of the present invention, the reticle alignment mark portion may be formed by a half-tone phase shift portion and a light shield area.

In the photomask of the present invention, the light shield area may be in the form of a cross mark, and the half-tone phase shift portion may be provided over a region except the light shield area.

In the photomask of the present invention, a region other than a product pattern portion may be formed as a light shield area.

In the photomask of the present invention, the half-tone phase shift portion has an exposure light transmittance lower than an alignment light transmittance.

In the photomask of the present invention, the photomask may be either one of a KrF half-tone phase shift mask, an i-ray half-tone phase shift mask, an ArF half-tone phase shift mask, and an F₂ half-tone phase shift mask.

A photomask according to the present invention has a half-tone phase shift portion in a reticle alignment mark portion instead of a light transmissive portion. Since the reticle alignment mark portion has a half-tone phase shift portion instead of a light transmissive portion, it is possible to reduce an exposure light transmittance and reduce an influence from ghost. As a result, it is possible to a photomask that is suitable for enhancement of fineness and has small variations of the pattern dimension.

The above and other objects, features, and advantages of the present invention will be apparent from the following description when taken in conjunction with the accompanying drawings which illustrate preferred embodiments of the present invention by way of example.

### BRIEF DESCRIPTION OF THE DRAWINGS

FIG. 1 is a graph showing measured values of the pattern dimension in the related art;

FIG. 2 is a plan view showing a photomask in the related art;

FIG. 3 is an enlarged view showing a reticle alignment mark portion in the photomask in the related art;

FIG. 4 is a plan view showing a photomask according to an embodiment of the present invention;

FIG. 5 is an enlarged view showing a reticle alignment mark portion in the photomask according to the embodiment of the present invention;

FIG. 6 is a diagram explanatory of exposure shots and positions where the pattern dimension is measured; and

FIG. 7 is a graph showing measured values of the pattern dimension according to the present invention.

### DETAILED DESCRIPTION OF THE PREFERRED EMBODIMENTS

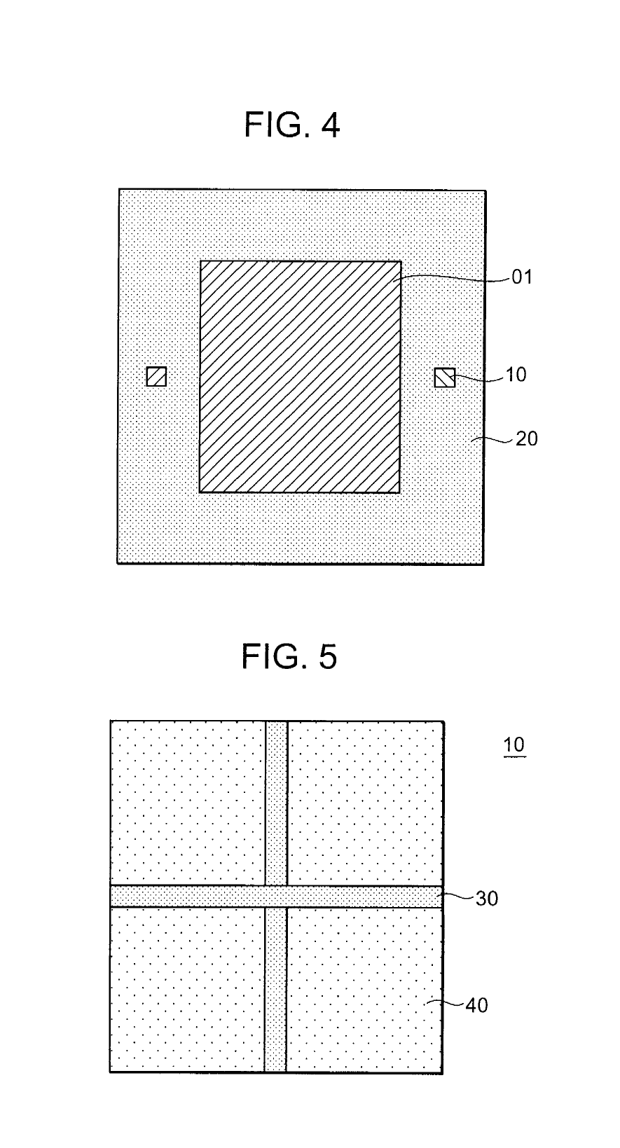

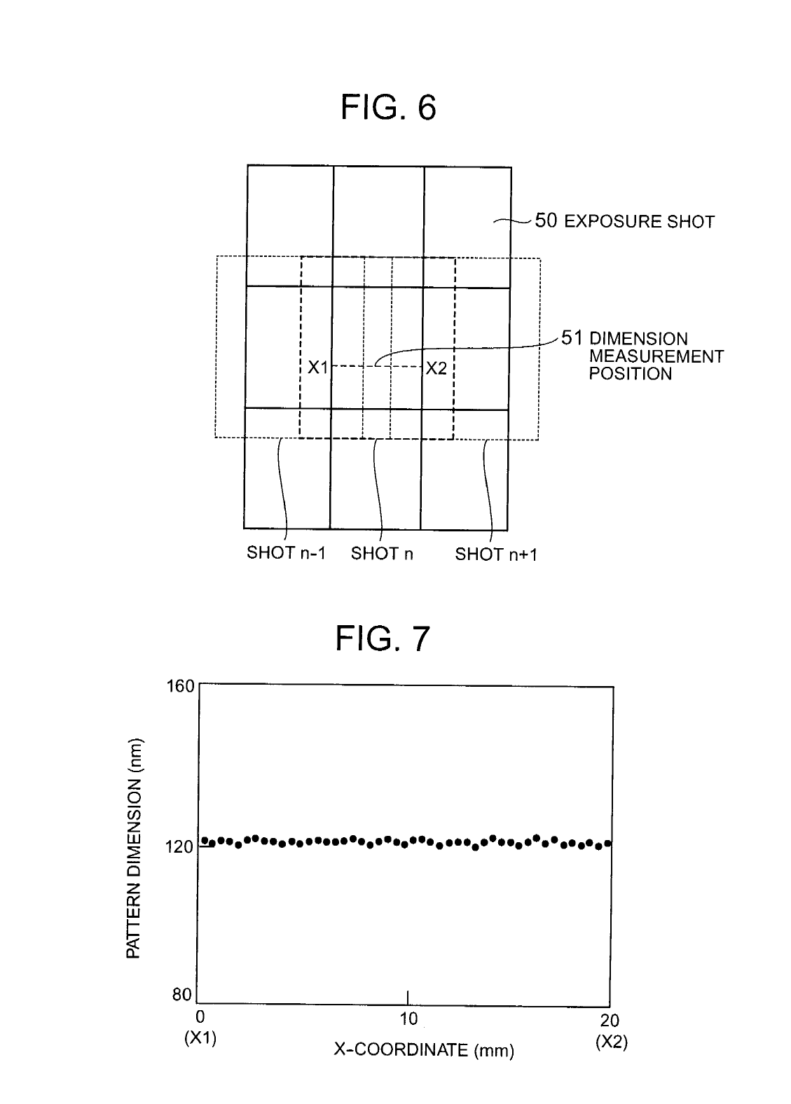

A photomask according to an embodiment of the present invention will be described below with reference to FIGS. 4 through 7. FIG. 4 is a plan view showing a photomask according to an embodiment of the present invention. FIG. 5 is an enlarged view showing a reticle alignment mark portion in the photomask shown in FIG. 4. FIG. 6 is a diagram explanatory of exposure shots and positions where the pattern dimension is measured. FIG. 7 is a graph showing measured values of the pattern dimension.

A photomask shown in FIG. 4 has a product pattern portion 01, a reticle alignment mark portion 10 located in an outer region around the product pattern portion 01, and a light shield area 20 located in the outer region except the reticle alignment mark portion 10. As shown in FIG. 5, the reticle alignment mark portion 10 has a light shield area 30 in the form of a cross mark and a half-tone phase shift portion 40 provided over a region except the cross mark. The half-tone phase shift portion 40 has the same structure as a half-tone phase shift portion in the product pattern portion 01. Furthermore, as shown in FIG. 4, the light shield area 20 extends over the entire outer region around the product pattern portion 01 except the reticle alignment mark portion 10.

For example, the photomask can employ KrF half-tone phase shift blanks (HOYA Corporation). In this case, the half-tone phase shift portion 40 of the photomask has a transmittance of 6% to a KrF excimer laser beam (wavelength: 248 nm). Furthermore, the half-tone phase shift portion 40 of the photomask has a transmittance of several tens of percent to visible light used for alignment. Thus, the photomask can be used for alignment of a reticle. The half-tone phase shift portion 40 of the photomask has a low exposure light transmittance. Accordingly, the half-tone phase shift portion 40 of the photomask is not treated as a light transmissive portion but as a light shield portion.

Next, use of the photomask will be described below.

In order to form a desired resist pattern on a semiconductor substrate, a chemical amplification positive photoresist for KrF excimer laser exposure is applied onto the semiconductor substrate. Then, the photomask is set in a KrF excimer laser exposure apparatus (aligner), and an exposure process is performed. When an exposure process is to be performed, relative positions of the photomask and a wafer stage are measured by the use of the reticle alignment mark portion 10 arranged on the photomask before the exposure process. After the position of the semiconductor substrate is measured by the use of the reticle alignment mark portion 10 formed on the semiconductor substrate in the preceding process, an exposure process is performed so that the pattern of the photomask is aligned at a predetermined position with the pattern formed on the semiconductor substrate. Thereafter, the exposed semiconductor substrate is baked on a hot plate and developed by an alkali developer. In this manner, a resist pattern is formed on the semiconductor substrate.

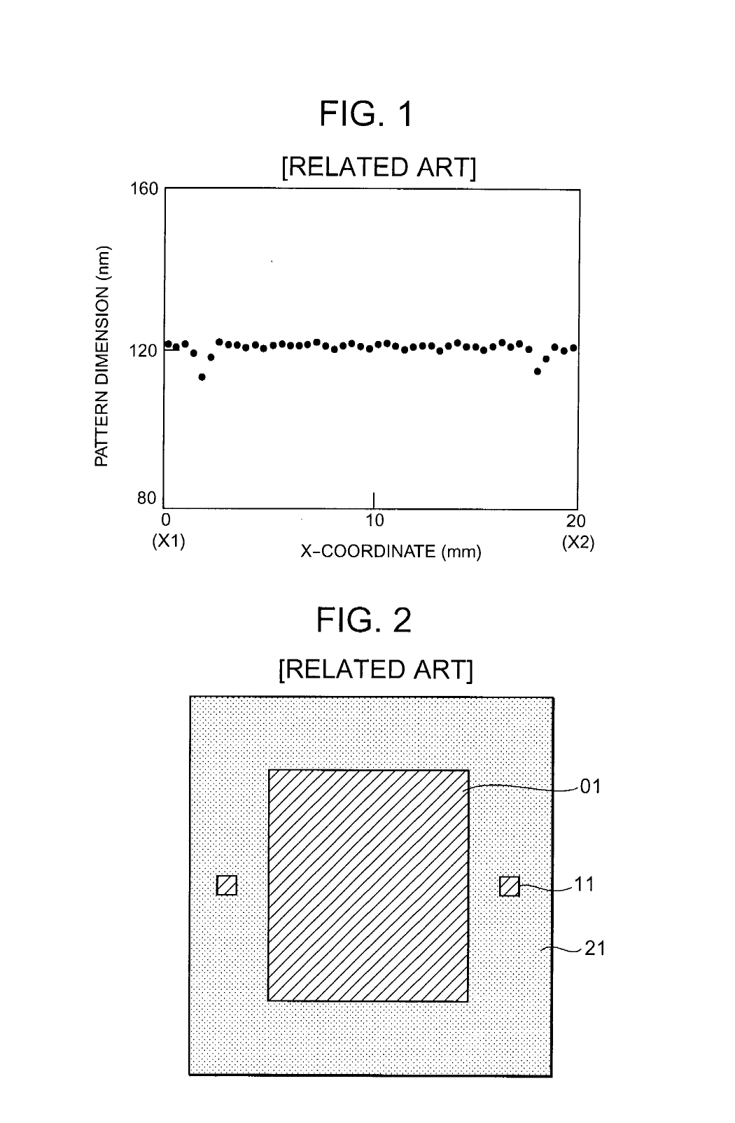

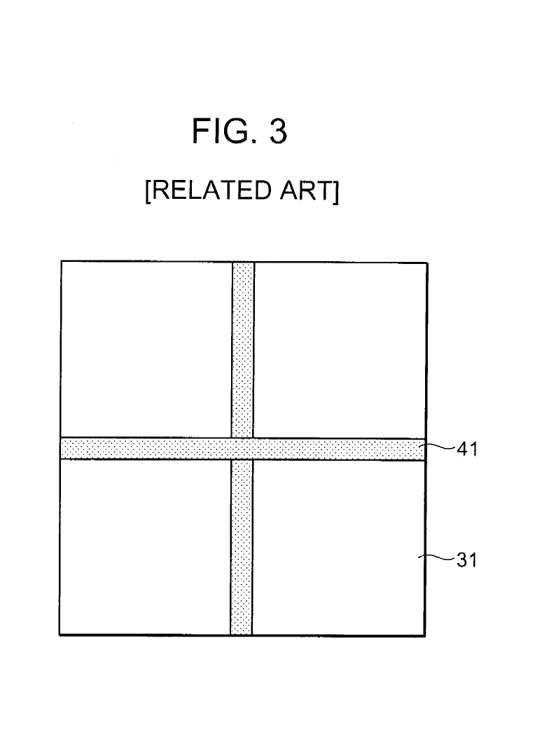

As shown in FIG. 6, one exposure shot 50 is taken in one exposure step. Exposure steps are repeated so as to expose the entire semiconductor substrate. The exposure shots 50 expose the region of the product pattern portion 01. When the dimension of the resist pattern formed on the semiconductor substrate was measured, it became uniform over all exposure shots as shown in FIG. 7. In contrast to this result, when a pattern was formed by the use of a related photomask shown in FIG.2, the dimension of the resist pattern was partially reduced as shown in FIG. 1. The portions where the dimension of the pattern was reduced were located near the reticle alignment mark portion 10 when an adjacent exposure shot was taken. The pattern dimension was reduced by light leaked from the reticle alignment mark portion 10 when an adjacent exposure shot was taken.

For example, exposure steps are repeated as a shot (n−1), a shot (n), and a shot (n+1). In this case, a portion of the product pattern portion for the shot (n) may be exposed at the time of the preceding exposure shot (n−1) by light leaked from the reticle alignment mark portion 10. Furthermore, a portion of the product pattern portion 01 for the shot (n) may be exposed at the time of the following exposure shot (n+1) by light leaked from the reticle alignment mark portion 10. Thus, portions of the product pattern portion 01 may be exposed at the time of the preceding and following shots (n−1) and (n+1) by light leaked from the reticle alignment mark portion 10. In those portions, the leaked light of the adjacent shots may overlap exposure light for exposing those portions, thereby causing an overexposure. Accordingly, the pattern dimension may be reduced at those portions. However, according to the present invention, the reticle alignment mark portion 10 has a half-tone phase shift portion instead of a light transmissive portion. Therefore, the amount of leaked light of adjacent shots is reduced, so that reduction of the pattern dimension is not caused.

Meanwhile, when the reticle alignment mark portion 10 is formed by a half-tone phase shift portion 40 and a light shield area 30 as shown in FIG. 5, an overlay error may be increased. However, in a case of a photomask according to present invention, an overlay error was measured as X=32 nm and Y=35 nm after formation of a resist pattern. In a case of a related photomask shown in FIG. 2, an overlay error (average value; ±σ) was measured as X=34 nm and Y=31 nm. Thus, the photomask according to present invention could achieve an overlay precision equivalent to the related photomask shown in FIG. 2 and did not increase an overlay error.

Although a KrF half-tone phase shift mask is used in the above embodiment, the half-tone phase shift mask is not limited by exposure wavelengths. Accordingly, the present invention is applicable to an i-ray half-tone phase shift mask, an ArF half-tone phase shift mask, and an F₂ half-tone phase shift mask. It is desirable that the half-tone phase shift portion 40 should have an exposure light transmittance sufficiently lower than that of glass and an alignment light transmittance (visible light transmittance) higher than the exposure light transmittance. It is also desirable that the half-tone phase shift portion 40 should have a high alignment light transmittance (visible light transmittance) to some extent, that is, at least several tens of percent.

According to the present invention, a region other than a product pattern portion is basically used as a light shield area. Therefore, it is possible to reduce an influence on pattern transfer from ghost. However, a reticle alignment mark portion in a photomask for overlay exposure should have a portion that allows light to pass therethrough. Accordingly, a half-tone phase shift portion is formed in the reticle alignment mark portion instead of a light transmissive portion. Use of the half-tone phase shift portion reduces an exposure light transmittance and reduces an influence from ghost. Thus, it is possible to reduce variations of the pattern dimension and pattern defects caused by ghost. As a result, a yield of products can be improved.

Although the present invention has been shown and described based on a preferred embodiment, it should be understood that the present invention is not limited to the illustrated embodiment. As a matter of course, various changes and modifications may be made therein without departing from the scope of the present invention and included in the scope of the present invention.

What is claimed is;:

1. A photomask for transferring a product pattern onto a semiconductor wafer, the photomask comprising:
a product pattern portion, and
a reticle alignment mark portion having no light transmissive portion.

2. The photomask according to claim 1, wherein:
the reticle alignment mark portion has a half-tone phase shift portion instead of the light transmissive portion.

3. The photomask according to claim 1, wherein:
the reticle alignment mark portion is formed by a half-tone phase shift portion and a light shield area.

4. The photomask according to claim 3, wherein:
the light shield area is in a form of a cross mark, and
the half-tone phase shift portion is provided over a region except the light shield area.

5. The photomask according to in claim 1, wherein:
a region other than the product pattern portion is formed as a light shield area.

6. The photomask according to claim 2 or 3, wherein:
the half-tone phase shift portion has an exposure light transmittance lower than an alignment light transmittance.

7. The photomask according to claim 1, wherein:
the photomask is any one of a KrF half-tone phase shift mask, an i-ray half-tone phase shift mask, an ArF half-tone phase shift mask, and an F₂ half-tone phase shift mask,
